(19) United States
(12) Patent Application Publication
(10) Pub. No.: US 2024/0362373 A1
(43) Pub. Date: Oct. 31, 2024

(54) APPARATUS AND METHOD FOR AUTOMATICALLY INSPECTING MACHINE COMPONENTS

(71) Applicant: NUOVO PIGNONE TECNOLOGIE SRL, Florence (IT)

(72) Inventors: Mirco INNOCENTI, Florence (IT); Andrea RUSSO, Florence (IT); Andrea GIORGETTI, Florence (IT); Remo RIBICHINI, Florence (IT)

(21) Appl. No.: 18/560,262

(22) PCT Filed: May 11, 2022
(86) PCT No.: PCT/EP2022/025221

§ 371 Date: Nov. 10, 2023

(30) Foreign Application Priority Data
May 17, 2021 (IT) 102021000012590

(51) Int. Cl. G06F 30/17; B25J 17/02; G01B 11/24

(52) U.S. Cl. CPC G06F 30/17; B25J 17/0283; G01B 11/24

(57) ABSTRACT

An inspection apparatus to automatically determine the state of a serviced machine component through a plurality of inspection phases; the apparatus includes: a computer unit, a 3D scanner, a plurality of inspection sensors for performing a plurality of inspection phases on the component; the computer unit interacts with the scanner and the sensors in order to generate an annotated 3D model of the component; the computer unit is configured to perform simulation on the machine component so to determine a status of one or more regions of the machine component; furthermore, the computer unit may be provided with a checking engine for applying one or more criteria to the results of the simulation and automatically determine whether the component is serviceable and/or repairable and generate a status report accordingly.

### TECHNICAL FIELD

The subject-matter disclosed herein relates to apparatuses and methods for automatically inspecting components particularly after a period of period of machine operations, i.e. so-called “serviced parts”.

### BACKGROUND ART

Components of a machine, for example machines for the Oil & Gas industry (in particular, turbomachines), may require to be checked after the machine has operated for some time in order to avoid failures and downtimes of the machine—typically, such checks are repeated periodically. This applies especially to components that are subject to wear and/or breakage which may be due, for example, to high temperature, high pressure, high mechanical stress, corrosion, erosion.

In order to perform some kinds of check, a machine may need to be totally or partially disassembled so that the component (or components) may be removed and subjected to inspection.

The result of such operation may be: that the component is in good state, i.e. “serviceable”, and may be mounted in the machine again as it is, that the component is not “serviceable” and needs to be repaired (somehow) before being mounted in the machine again, that the component is neither “serviceable” nor “repairable” and that a new component must be mounted in the machine.

Systems are known for performing specific inspection phases. For example, patent document US 2017/0176342 A1 discloses a system for inspecting turbine blades; a computer may compare differences between input from a scanner and a predetermined ideal blade surface with predetermined thresholds; the computer may create a report describing predicted changes in efficiency or performance that may occur after pursuing a recommended repair of the blade surface (corresponding to the difference between actual efficiency or performance and ideal efficiency or performance). Additionally, software systems are known, e.g. from US 2007/217672 A1 and US 2014/207419 A1, for assisting a human inspector in visually inspecting a machine component by building an annotated 3D model of the component and presenting it to the inspector on a computer screen; as usual, the point-by-point assessment of the state of the component is manual and is based on the training and the experience of the inspector.

However, the overall inspection and assessment procedure is still essentially manual even if some specific inspection phases may be automated.

### SUMMARY

Therefore, it would be desirable to improve the inspection procedure, in particular, to offer inspection procedure of components of machines that is performed automatically. It is to be understood that herein the word “component” is to be interpreted broadly as including any part of a machine that may be subject to inspection after machine operation; the solutions described herein are most advantageously used for mechanical objects.

According to a first aspect, the subject-matter disclosed herein relates to an inspection apparatus that allows to automatically determine the state of a serviced machine component through a plurality of inspection phases; the apparatus includes: a computer unit, a 3D scanner, a plurality of inspection sensors for performing a plurality of inspection phases on the component; the computer unit interacts with the scanner and the sensors in order to generate an annotated 3D model of the component. The computer unit is configured to perform a simulation on the machine component so to determine a status of one or more regions of the machine component. Furthermore, the computer unit may be provided with a checking engine for applying one or more criteria to the results of the simulation and automatically determine whether the component is serviceable and/or repairable. Based on such determination, a status report may be issued by the computer unit for a user of the inspection apparatus; for example, the status report may be output through a user interface of the computer unit and/or stored in a memory of the computer unit for future use.

According to a second aspect, the subject-matter disclosed herein relates to a method for inspecting a serviced machine component; the method includes an initial phase and afterwards one or more different inspection phases; during the initial phase, the component is scanned and a 3D model of the component is created; the inspection phases allow to create an annotated 3D model of the component. Furthermore, the method may include a final phase during which a simulation is performed so to determine a status of one or more regions of the machine component and then one or more criteria are applied to the results of the simulation so to determine whether the component is serviceable and/or repairable.

### BRIEF DESCRIPTION OF THE DRAWINGS

A more complete appreciation of the disclosed embodiments of the invention and many of the attendant advantages thereof will be readily obtained as the same becomes better understood by reference to the following detailed description when considered in connection with the accompanying drawings, wherein:

FIG. 1 shows a very general schematic diagram of an inspection apparatus;

FIG. 2 shows a schematic diagram of a first embodiment of an inspection apparatus;

FIG. 3 shows a schematic diagram of a second embodiment of an inspection apparatus; and

FIG. 4 shows a flow chart of an embodiment of an inspection method.

### DETAILED DESCRIPTION OF EMBODIMENTS

An innovative inspection apparatus allows to automatically determine the state of a serviced machine component, for example whether the component is worn or broken, through a plurality of inspection phases carried out one after the other. The apparatus includes a scanner and plurality of sensors that are controlled by a computer in order to automatically create a computerized representation of the component (obtained from the scanner) with associated information (obtained from the sensors) regarding the state of the various portions of the component; in this way, an “annotated 3D model” of the component may be generated. Such “annotated 3D model” is easy to be automatically processed by computers. Such “annotated 3D model” of the component may be used, for example, to determine whether the component is serviceable and/or repairable by performing simulation, for example a mechanical or thermal simulation, on the component and then automatically “applying” one or more criteria to the results of the simulation; in this way, an overall assessment of the e.g. mechanical or thermal status of the component (as it is) even under machine operation conditions is possible but while the component is dismounted from the machine.

Reference now will be made to embodiments of the disclosure that are illustrated in the drawings. The embodiments are provided by way of explanation of the disclosure, not limitation thereof. In fact, it will be apparent to those skilled in the art that various modifications and variations can be made in the present disclosure without departing from the scope or spirit of the disclosure.

The innovative inspection apparatus is useful for determining a state of a machine component (that can be called also “machine part”) that has already been used in a machine for some time during operation of the machine, i.e. a so-called “serviced part”. Such state may refer to, for example, any deformation of the component (e.g., change of overall shape and/or change of overall size) and/or any change in a surface geometry (e.g. local loss of material, for example due to erosion or corrosion, or local deposition of material, for example total or partial obstruction of a hole) and/or any change in a surface layer or a sub-surface layer (e.g., reduction in the thickness of a protection layer or a superficial or deep crack) and/or a change in a core of the component and corresponding effect(s) on the mechanical status (e.g. the shear stress, the tensile stress, the torsion) and/or the thermal status (e.g. the temperature) and/or the chemical status (e.g. the oxidation) of one or more regions of the component in particular when the component in under machine operation conditions; it is to be noted that other statuses may be considered, for example electric status, magnetic status, optical status, electromagnetic status. The first inspected and then assessed component was previously dismounted from a machine.

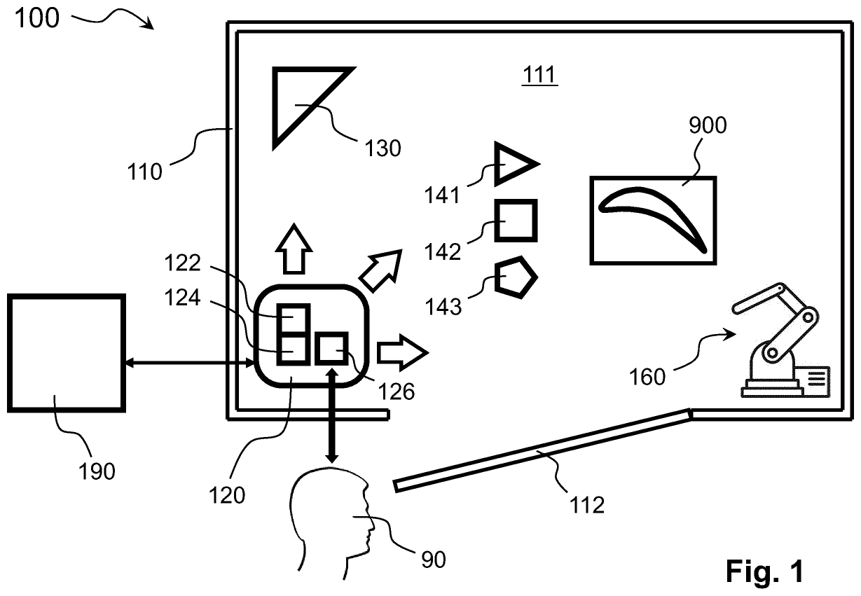

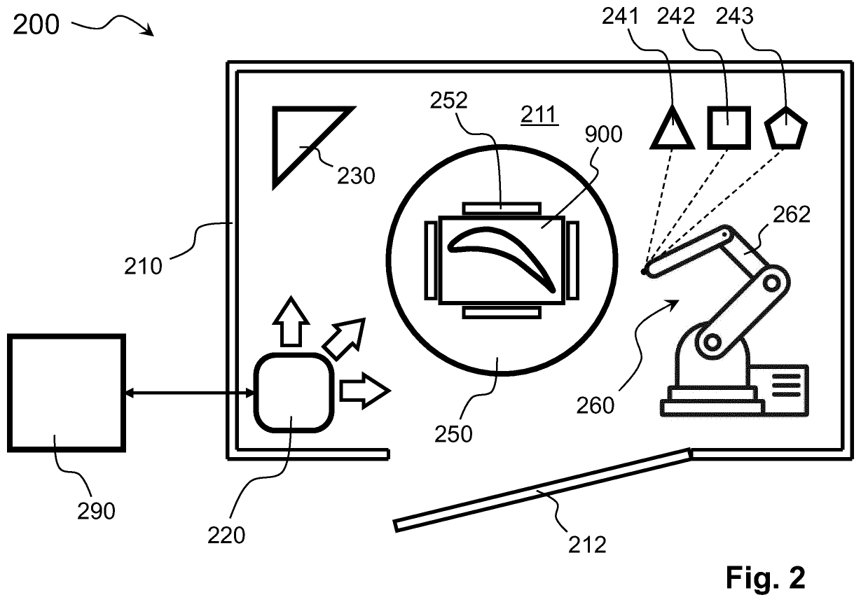

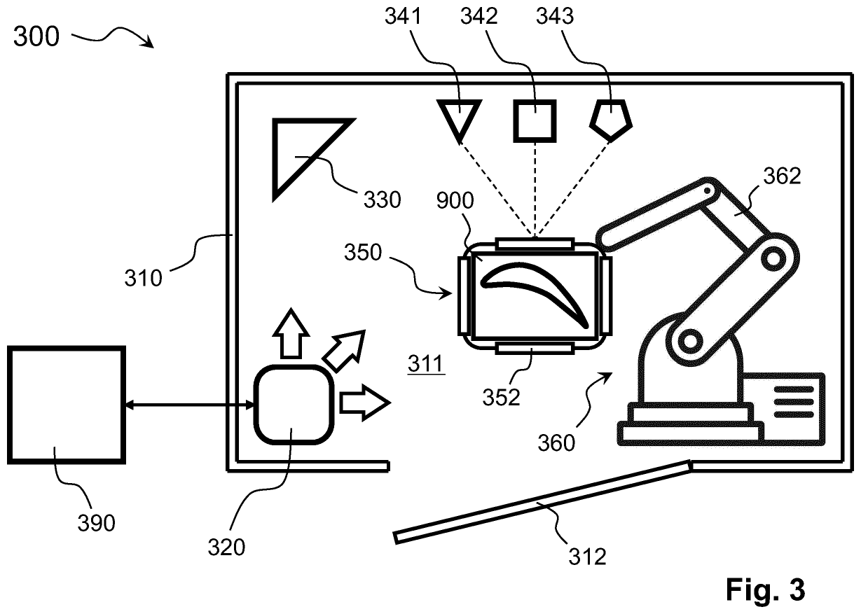

In FIG. 1, FIG. 2 and FIG. 3 the mechanical component 900 to be inspected is schematically shown and is, for example and without limitation, a blade of a turbine including a base portion and an airfoil portion. It is to be understood that innovative apparatuses and methods according to the present disclosure may be used for inspecting other machine parts, for example the so-called “gas turbine hot gas path parts” (“HGPP”) and the so-called “combustion parts” (“CC”).

According to these embodiments, one component 900 at a time is introduced into an inspection room 111 of a container 110 before being inspected; the container 110 has walls and an opening, typically having a door 112, for accessing the inspection room 111 and introducing the component 900. Container 110 may be equal or similar to a freight container and may be transportable so to allow inspection of machine components directly where the machine is installed, for example at Oil & Gas processing plant. It is to be noted that according to some embodiments the container may be avoided.

FIG. 1 schematically shows an inspection apparatus 100 including at least a computer unit 120, a 3D scanner 130, a plurality of inspection sensors 141, 142, 143, and an industrial robot 160 with an articulated arm. The computer unit 120 may include i.a. a processor or a controller or a microprocessor or the like (not shown), a data memory (not shown), a program memory (not shown), a user interface 126 for users that are schematically shown as 90 in FIG. 1. As shown in the figure, all these elements may be housed in the container 110. As shown in the figure, the computer unit 120 may be electrically coupled with an external computer system 190 through a wired connection and/or a wireless connection including, for example, the Internet or another computer network. The big arrows departing from unit 120 in the figure indicate the possibility that the computer unit 120 controls for example the scanner 130, the inspection sensors 141, 142, 143, and the industrial robot 160, but includes the possibility that the computer unit 120 receives data and/or information from them, in particular from the scanner and the inspection sensors. It is to be noted that even if the scanner is shown in the figures as a separate device distinct and different from the inspection sensors, according to some embodiments the scanner may correspond to an optical inspection sensor configured to move with respect to the machine component; there are three possibilities: 1) only the sensor makes absolute movements, 2) only the component makes absolute movements, 3) both the sensor and the component make absolute movements. In the following, when reference will be made to functions performed by the inspection apparatus essentially through a program or programs, that may be “software” or “firmware”, stored in the program memory of the computer unit, the expression “arranged to” will be used.

In FIG. 1, three inspection sensors 141, 142, 143 are shown that are 5 different from each other (this is represented by the different shapes of their symbols); however, a different number may be considered, the minimum number being one, but the typical number being greater than one. Any of these sensors may be for example:
an optical sensor, in particular white-light interferometry sensor or laser sensor,
a borescope sensor,
an electromagnetic waves sensor, in particular microwave probe sensor,
an inductive sensor, in particular eddy current sensor,
an induction or infrared thermography sensor,
an ultrasonic sensor,
a fluorescence sensor, in particular X-ray fluorescence sensor;
   for example, sensor 141 may be a borescope sensor for accessing e.g. the integrity of cavities (for example holes), sensor 142 may be a thermography sensor for accessing e.g. the integrity of thermal barriers, sensor 143 may be an eddy current sensor for accessing e.g. the integrity of a surface and/or a sub-surface layer from the mechanical point of view (for example the presence of cracks or voids).

In general, an innovative inspection apparatus (like e.g. apparatus 100 in FIG. 1) comprises:
a computer unit (like e.g. unit 120 in FIG. 1),
a scanner (like e.g. 3D scanner 130 in FIG. 1, that may be laser or white light) configured to scan a machine component (like e.g. component 900 in FIG. 1)—the computer unit is coupled with the scanner and is arranged to create a 3D model of the component based on the scanning of the component, and
a plurality of inspection sensors (like e.g. sensors 141, 142, 143 in FIG. 1) configured to perform a corresponding plurality of inspection phases on the component—the computer unit is configured to be coupled with each of the inspection sensors, typically one after the other, and is arranged to create an annotated 3D model of the component based on the 3D model of the component and data received from the inspection sensors.

For example, considering FIG. 1 the operation could be as follows:
the computer unit 120 may connect to and control the scanner 130, receives scanning data, and create a 3D model of the component based on the scanning data—typically, scanning data are received while relative movements occur between parts of the scanner and the component, then
the computer unit 120 may connect to and control the first sensor 141, receives first sensing data, generates first inspection information from the first sensing data, and associate the first inspection information to the current 3D model of the component so to create a 3D model of the component with added first annotations (for example diameters and depth at each hole of the component)—typically, first sensing data are received while relative movements occur between parts of the first sensor and the component, then
the computer unit 120 may connect to and control the second sensor 142, receives second sensing data, generates second inspection information from the second sensing data, and associate the second inspection information to the current 3D model of the component so to create a 3D model of the component with added second annotations (for example quality of the thermal barrier at each point where there is a thermal barrier on the surface of the component)—typically, second sensing data are received without substantial movements between parts of the second sensor and the component, then
the computer unit 120 may connect to and control the third sensor 143, receives third sensing data, generates third inspection information from the third sensing data, and associate the third inspection information to the current 3D model of the component so to create a 3D model of the component with added third annotations (for example under-surface missing material at each point of the surface of the component)—typically, third sensing data are received while relative movements occur between parts of the third sensor and the component. Therefore, considering FIG. 1, the resulting annotated 3D model of the component may contain the precise external shape of the component under inspections as well as three types of annotations associated to various positions of the component; such annotated 3D model is easy to be automatically processed by computers afterwards.

The computer unit (like e.g. unit 120 in FIG. 1) of the innovative inspection apparatus is configured to receive and/or retrieve a design model of the machine component to be assessed (like e.g. component 900 in FIG. 1). The design model is retrieved if it is stored in a memory device, for example a hard disk, of the computer unit and is received if it is stored in a memory device, for example a hard disk, of a different and remote computer system. The design model is used to obtain detailed information regarding the machine component (for example, ideal surface geometry and/or internal structure and/or materials and manufacturing steps and/or treatments and/or operating conditions and/or relations with other machine components). Retrieval and reception may require that the machine component is previously identified based on e.g. input received from a user.

The computer unit (like e.g. unit 120 in FIG. 1) of the innovative inspection apparatus is configured to perform a e.g. mechanical or thermal or chemical simulation on the machine component (like e.g. component 900 in FIG. 1) so to determine e.g. a mechanical status (e.g. the shear stress, the tensile stress, the torsion) or a thermal status (e.g. the temperature) or a chemical status (e.g. the oxidation) of one or more regions of the machine component. Such simulation takes into account the created 3D model of the machine component (for example the actual surface geometry of the whole component), inspection data generated from at least one inspection phase (for example actual non-visible characteristics of the component), and the received and/or retrieved design model of the machine component (for example, ideal surface geometry and/or internal structure and/or materials and manufacturing steps and/or treatments and/or operating conditions and/or relations with other machine components). Such simulation is preferably performed under machine operation conditions if the results of the simulation is influenced by these conditions.

The computer unit (like e.g. unit 120 in FIG. 1) of the innovative inspection apparatus comprises a checking engine, which is typically one or more pieces of firmware and/or software that may be provided with configuration data and/or that may be stored for example in the program memory of the computer unit; the configuration data may include one or more serviceable criteria (see e.g. box 122 in FIG. 1) and/or one or more repairable criteria (see e.g. box 124 in FIG. 1), and/or may be stored for example in the data memory of the computer unit.

The checking engine may be arranged to apply one or more criteria to the results of the simulation performed and based on such criteria application determine whether the machine component is serviceable. It is to be expected that such serviceability criteria are determined by the designer/manufacturer of the machine and its components; however, the user of the machine (for example the customer of the manufacturer) may contribute at least to some of the serviceability criteria. The serviceability criteria (shown for example as 122 in FIG. 1) may be stored into the computer unit at the time of manufacturing the machine and/or at the time of installing the machine; according to some embodiments, they may be changed after installation. The checking engine may be arranged to generate a status report of the machine component for a user (exemplary shown as 90 in FIG. 1) based on for example the serviceable determination. A status report including serviceability data may be issued be output through a user interface (shown for example as 126 in FIG. 1) of the computer unit, for example its display, and/or stored in a memory of the computer unit for future use.

Alternatively or additionally, the checking engine may be arranged to apply one or more criteria to the results of the simulation performed and based on such criteria application determine whether the machine component is repairable. It is to be expected that such repairability criteria are determined by the designer/manufacturer of the machine and its components; however, the user of the machine (for example the customer of the manufacturer) may contribute at least to some of the repairability criteria. The repairability criteria (shown for example as 124 in FIG. 1) may be stored into the computer unit at the time of manufacturing the machine and/or at the time of installing the machine; according to some embodiments, they may be changed after installation. The checking engine may be arranged to generate a status report of the machine component for a user (exemplary shown as 90 in FIG. 1) based on for example the repairable determination. A status report including repairability data may be issued be output through a user interface (shown for example as 126 in FIG. 1) of the computer unit, for example its display, and/or stored in a memory of the computer unit for future use.

It is to be noted that, according to the prior art, the inspection information are assessed (manually) point-by-point and compared with reference information. For example, if a lack of thermal-insulation coating is detected at a first point of a surface of a component, its size is compared with two threshold values, and the component is judged serviceable, repairable or to-be-discarded depending on such two comparisons; afterwards, if a lack of thermal-insulation coating is detected at a second point of the surface of the component, the same procedure is repeated. However, according to the prior art, the overall effect of the various lacks of thermal-insulation coating is not considered. On the contrary, as disclosed herein, by (automatically) simulating the temperature distribution of the machine component (i.e. the actual component as scanned and inspected with all its lacks), preferably under machine operation conditions, it is possible to (automatically) consider for example the effects of all lacks of thermal-insulation coating and the simulated temperature at one or more points of the components may be (automatically) compared with e.g. two threshold values (that may be different from point to point).

As it is apparent from FIG. 1, the functions of the checking engine may be variously split between the internal computer unit (e.g. unit 120) and the external computer system (e.g. system 190), depending on the embodiment. Therefore, according to some embodiments, the internal computer unit is arranged to create an annotated 3D model of the component and transmit it to the external computer system, and the external computer system is arranged to receive an annotated 3D model, to perform simulations and to apply one or more criteria—alternatively, the annotated 3D model may be shared between the internal computer unit and the external computer system; in this way, the serviceability and/or repairability outcome data may derive from a cooperation between the internal computer unit and the external computer system. The external computer system may be considered part of an innovative inspection apparatus.

Typically, the computer unit (like e.g. unit 120 in FIG. 1) may be arranged to identify the specific component to be inspected (for example turbine blade part no e.g. SMH48303) or a category of the component to be inspected (for example “blade for high-power turbines”); in fact, it is to be expected that the inspection phases to be carried out and/or the sequence of phases and/or the criteria to be applied depend on any or both of them. Such identification may be based on input received by the apparatus from a user (see e.g. 90 in FIG. 1); for example, before introducing a component into the inspection room of the apparatus, an operator may digit a corresponding code through a keyboard (see e.g. 126 in FIG. 1) of the computer unit. Such identification may be based on input received by a code reader arranged to read a code marked on the component to be inspected. Such identification may be based on scanning and automatically recognizing the component to be inspected.

The computer unit (like e.g. unit 120 in FIG. 1) may be arranged to receive and/or retrieve a design model of the component to be inspected. For example with reference to FIG. 1, unit 120 may communicate with system 190 and obtain the design model from a design database storing models of the components of several different machines as they were originally designed by design engineers. It is to be noted that the term “design model” is not to be interpreted as limited to the shape of the component, but may include other characteristics such as tolerances and/or materials and/or manufacturing treatments and/or test procedure and/or inspection procedure; for example, the “model-based engineering (MBE)” is an approach to engineering that uses models as an integral part of the technical baseline that includes the requirements, analysis, design, implementation, and verification of a capability, system, and/or product throughout the acquisition life cycle.

The computer unit (like e.g. unit 120 in FIG. 1) may be arranged to correlate the 3D model of the component derived from its scanning in the inspection apparatus with its design model. For example, by comparing (which is a form of correlation) the 3D model with the design model it is possible to determine any deformation in the component occurred due to its use in the machine. It is possible that the inspection phases to be carried out and/or the sequence of phases and/or the criteria to be applied depend on the design model of the component to be inspected.

The computer unit (like e.g. unit 120 in FIG. 1) may be arranged to apply criteria based on a simulation performed on the specific component to be inspected. The simulation may be performed by the internal computer unit or by an external computer system that provides the results of the simulation to the internal computer unit. The simulation may consist in evaluating of the durability of the specific component to be inspected in terms of oxidation or creep or LCF or HCF or crack propagation lives or FMEA based on analytical and/or statistical models.

It is to be noted one or more of the criteria may be based on a duration and/or a condition of the period of machine operation of the machine component to be accessed. For example, if a component has been in use for several years. it is to be expected that the thickness of any of its coatings is reduced with respect to its design value or that the sealing of any of its gasket is reduced with respect to its design value. Such changes may depend not only on operation time but also on operation conditions.

It is to be noted one or more of the criteria may be a multiple criterion; for example, such criterion may correspond the combination (for example a logical combination) of a first check on inspection information from a first inspection phase and a second check on inspection information from a second inspection phase.

Advantageously, some or all inspection sensors of the plurality of inspection sensors are non-contact type, i.e. the sensor does not need to touch the surface of the component to be inspected; in any case, touching the surface may be accepted (even if not necessary) so that the positioning of the sensor requires less precision. It is not to be excluded that one or more of the inspection sensors may be contact type; however, in this case, not only some precision in the positioning may be required but also some control on the pressure applied to the component surface.

Typically, the plurality of inspection sensors comprises at least one inspection sensor for inspecting a surface geometry and at least one inspection sensor for inspecting a surface layer or a sub-surface layer. It is not to be excluded that the plurality of inspection sensors may comprise at least one inspection sensor for inspecting a core of the component, i.e. portions of the internal volume.

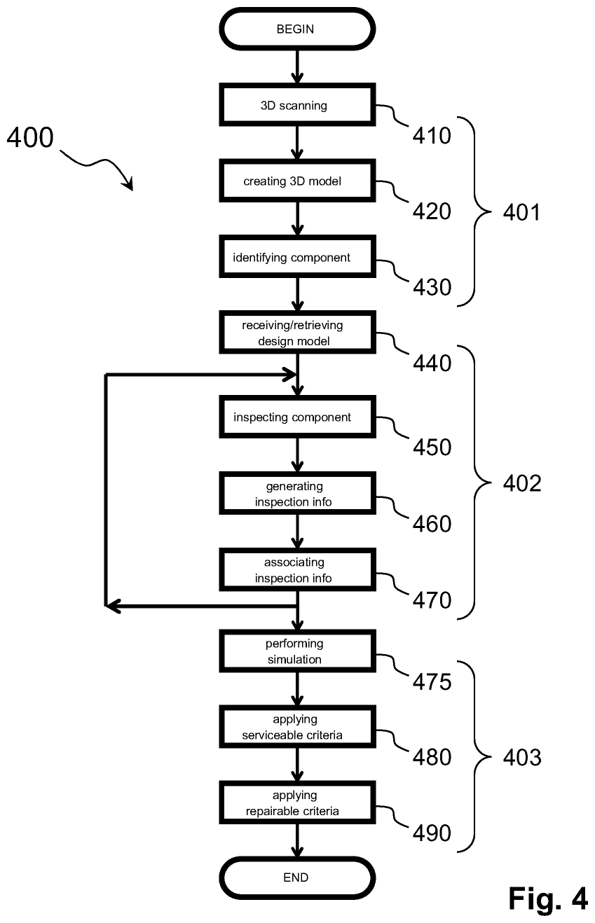

FIG. 2 and FIG. 3 refer respectively to a first embodiment 200 of an innovative inspection apparatus and a second embodiment 300 of an innovative inspection apparatus. However, before entering into such details, an inspection method will be described with the aid of the flow chart 400 of FIG. 4 and the block diagram of FIG. 1.

The method is useful for inspecting components after a period of machine operation, such as component 900 in FIG. 1, (even if one could use it for inspecting also new components), and comprises an initial phase 401 (that may be called “modelling phase”), afterwards one or more different inspection phases 402 (considering FIG. 1, three inspection phase are to be performed, typically one after the other), and afterwards a final phase 403 (that may be called “checking phase”). It is to be noted that the method may be performed close to or far from the machine where the component has been used. Additionally, it is to be noted that the final phase 403 may be performed well after the inspection phase and in a place different from where the inspected component is. Finally, it is to be noted that the final phase 403 may be performed by an apparatus different from the inspection apparatus that has performed the initial phase 401 and the inspection phases 402; such inspection apparatus may be identical or similar to the inspection apparatuses disclosed herein and may comprise a computer unit.

According to the embodiment of FIG. 4, the initial phase 401 comprises the steps of:
A) scanning (block 410) the machine component dismounted from the machine,
B) creating (block 420) a 3D model of the machine component based on the scanning of the machine component,
C) identifying (block 430) the machine component or a category of the machine component based on input received from a user, and
D) receiving and/or retrieving (block 440) a design model of the machine component.

Considering FIG. 1, the initial phase 401 is essentially carried out through unit 120 and scanner 130; robot 160 may also contribute.

According to the embodiment of FIG. 4, an inspection phase 402 comprises the steps of:
E) inspecting (block 450) the machine component through at least one inspection sensor,
F) generating (block 460) inspection information based on the at least one inspecting step, and
G) associating (block 470) the inspection information to the 3D model of the machine component so to create an annotated 3D model of the machine component—as explain previously, typically, the 3D model is incrementally annotated based on inspection information from several inspection phases.

Considering FIG. 1, an inspection phase 402 is essentially carried out through unit 120, robot 160 and any of sensors 141, 142 and 143.

According to the embodiment of FIG. 4, the final phase 403 comprises the steps of:
I) performing (block 475) an e.g. mechanical or thermal or thermal simulation on the machine component so to determine a e.g. mechanical or thermal or chemical status of one or more regions of the machine component, taking into account the created 3D model of the machine component, inspection data generated from at least one inspecting step, and the received and/or retrieved design model of the machine component;
H) applying (block 480) one or more criteria to the results of the e.g. mechanical or thermal or chemical simulation performed so to determine whether the machine component is serviceable, and/or
L) applying (block 490) one or more criteria to the results of the e.g. mechanical or thermal or chemical simulation performed so to determine whether the machine component is repairable.

Considering FIG. 1, the final phase 403 is essentially carried out through unit 120 and/or system 190 based on inspection criteria 122 and/or 124; according to the embodiment of FIG. 1, all the criteria are stored in unit 120. The serviceable determination and/or the repairable determination may be used for issuing a status report with serviceability data and/or repairability data for example in the form of a list of various inspection results; the status report may be output to a user for example by the computer unit, in particular its display, and/or stored for example in a memory of computer unit and then possibly all or part of the status report may be transferred to an external computer system. It is to be noted that, according to some embodiments, the status report may contain only a selection of serviceability data and/or repairability data, for example only positive inspection results or only negative inspection results.

Preferably and advantageously, the simulation performed at step I is performed under machine operation conditions. Furthermore, advantageously, at least one of the criteria at step H and/or L may be based on a duration and/or a condition of the period of machine operation, Finally, at least one of the criteria at step H and/or L may be a multiple criterion, wherein a multiple criterion is based on at least two inspection steps.

A first embodiment 200 of an innovative inspection apparatus will be described in the following with the aid of FIG. 2. It is to be noted that elements 210, 211, 212, 220, 230, 241, 242, 243, 260 and 290 in FIG. 2 may be identical or similar respectively to elements 110 (container), 111 (inspection room), 112 (door), 120 (internal computer unit), 130 (scanner), 141 (first inspection sensor), 142 (second inspection sensor), 143 (third inspection sensor), 160 (robot), 162 (articulated arm) and 190 (external computer system) in FIG. 1 and perform the same or similar functions.

The apparatus 200 of FIG. 2 comprises a support element 250, in particular a table, for supporting the component 900 to be inspected. The support element 250 may comprise a fixture 252 dedicated to the component to be inspected; for example in FIG. 2, the base portion of the turbine blade fits perfectly between, e.g., four fixed members 252 of the support element 250. The support element 250 may be rotatable and or tiltable.

The support element 250 may be rotatable and or tiltable. If the support element 250 is movable, the computer unit 220 may be arranged to control movement of the support element 250. If the support element 250 is movable, it may contribute to the scanning of the component 900; for example, scanning may occur during rotation and/or tilting of the support element 250 and the corresponding rotation and/or tilting of the supported component 900.

The apparatus 200 of FIG. 2 comprises at least one industrial robot 260 with an articulated arm 262, preferably a five-axis or six-axis articulated arm; the articulated arm 262 is configured to carry an inspection sensor and the computer unit 220 is arranged to control movement of the articulated arm 262. The robot 260 may also contribute to the scanning of the component 900; for example, the arm 262 may carry an optical sensor and may move around the component 900 in order to scan it; in this case, scanner 230 may correspond to an optical sensor to be carried by the articulate arm of the robot. According to preferred embodiments, the apparatus has only one robot for inspecting the component. According to preferred embodiments, the apparatus has only one robot for repairing the component.

Typically, the articulated arm 262 is configured to carry alternatively two or more inspection sensors and the computer unit 220 is arranged to control change of sensor carried by the arm; in FIG. 2, the dashed lines connecting the sensors and the end of the arm member, show schematically to actions to pick a sensor from its resting position, perform an inspection on the component and return the sensor to its resting position.

The computer unit 220 is arranged to move an inspection sensor along an inspection path (that may depend on component and on the sensor).

A second embodiment 300 of an innovative inspection apparatus will be described in the following with the aid of FIG. 3. It is to be noted that elements 310, 311, 312, 320, 330, 341, 342, 343, 360 and 390 in FIG. 3 may be identical or similar respectively to elements 110 (container), 111 (inspection room), 112 (door), 120 (internal computer unit), 130 (scanner), 141 (first inspection sensor), 142 (second inspection sensor), 143 (third inspection sensor), 160 (robot), 162 (articulated arm) and 190 (external computer system) in FIG. 1 and perform the same or similar functions.

The apparatus 300 of FIG. 3 comprises at least one industrial robot 360 with an articulated arm 362, preferably a five-axis or six-axis articulated arm; the articulated arm 362 is configured to carry the component 900 to be inspected, and the computer unit 320 is arranged to control movement of the articulated arm 362. The articulated arm 362 may comprise a fixture 350 dedicated to the component to be inspected; for example in FIG. 3, the base portion of the turbine blade fits perfectly between, e.g., four fixed members 352 of the fixture 350. In this way, the industrial robot, in particular the articulated arm, may be configured to grasp, move and/or manipulate the machine component.

The articulated arm 362 may be arranged to (fixedly or movably) carry the machine component 900 to be inspected when the scanner 330 performs scanning of the component.

According to the embodiment of FIG. 3, some or all inspection sensors 341, 342, 343 are fixedly mounted to a frame or structure of the apparatus 300 at different positions (in FIG. 3 they are represented, for example, close to a wall of the container 310).

According to the embodiment of FIG. 3, the computer unit 320 is arranged to move the machine component 900 to be inspected along an inspection path. It is to be noted that a first portion of the inspection path may be the moving of the component close to an inspection sensor, a second portion of the inspection path (that may depend on component and on the sensor) may be the moving of the component within a zone of the inspection sensor while the sensor is active so to perform the desired inspection, a third portion of the inspection path may be the moving of the component far from the inspection sensor. In FIG. 3, the dashed lines connecting the sensors and the fixture, show schematically the various first portions and third portions of the inspection paths for inspection sensors 341, 342, 343.

The essential difference between the first embodiment of FIG. 2 and the second embodiment of FIG. 3 is that, during inspection phases, according to the first embodiment the component is fixed (apart from possible rotating and/or tilting of the support element) and the sensors move while according to the second embodiment the sensors are fixed and the component moves. It is evident that other embodiments may correspond to a combination of these two alternatives.

In the light of the above, it is apparent that the innovative apparatus and method disclosed herein are provide inspection possibilities far from those provided by apparatuses and methods according to the prior-art, especially those aimed at assisting human inspectors. According to the prior-art, the results of inspections were directly compared with reference data.

1. An inspection apparatus for determining automatically a state of a machine component after a period of machine operation based on a plurality of inspection phases, the machine component being already used in a machine, the apparatus comprising:
a computer unit,
a scanner configured to scan the machine component dismounted from the machine, wherein the computer unit is coupled with the scanner and is arranged to create a 3D model of the machine component based on the scanning of the machine component,
a plurality of inspection sensors configured to perform a corresponding plurality of inspection phases on the machine component, wherein the computer unit is configured to be coupled with each of the inspection sensors and is arranged to generate inspection information from each of the inspection phases and correspondingly associate the inspection information to the 3D model of the machine component so to create an annotated 3D model of the machine component;
wherein the computer unit is configured to receive and/or retrieve a design model of the machine component;
wherein the computer unit is configured to perform a simulation on the machine component so to determine a status of one or more regions of the machine component, taking into account the created 3D model of the machine component, inspection data generated from at least one inspection phase, and the received and/or retrieved design model of the machine component,
wherein the computer unit comprises a checking engine including one or more serviceable criteria, the checking engine being arranged:
to apply the one or more serviceable criteria to results of the performed simulation performed,
to determine whether the machine component is serviceable based on the serviceable criteria application, and
to generate a status report of the machine component for a user based on the serviceable determination.

2. The inspection apparatus of claim 1, wherein the checking engine includes one or more repairable criteria, and is further arranged:
to apply the one or more repairable criteria to results of the performed simulation performed,
to determine whether the machine component is repairable based on the repairable criteria application;
wherein the status report of the machine component is also based on the repairable determination.

3. The inspection apparatus of claim 1, wherein the computer unit is configured to perform a mechanical or thermal or chemical simulation on the machine component so to determine a mechanical or thermal or chemical status of one or more regions of the machine component.

4. The inspection apparatus of claim 1, wherein at least one of the criteria is predetermined and associated to the machine component or a category of the machine component.

5. The inspection apparatus of claim 1, wherein at least one of the criteria is based on a design model of the machine component.

6. The inspection apparatus of claim 1, wherein at least one of the criteria is based on a duration and/or a condition of the period of machine operation.

7. The inspection apparatus of claim 1, wherein at least one of the criteria is a multiple criterion, wherein a multiple criterion is based on at least two inspection phases.

8. The inspection apparatus of claim 1, wherein the computer unit is arranged to determine a sequence of inspection phases based on the machine component or a category of the machine component.

9. The inspection apparatus of claim 1, wherein the computer unit is arranged to identify the machine component and/or a category of the machine component based on input received from a user of the inspection apparatus.

10. The inspection apparatus of claim 1, wherein the simulation is performed under machine operation conditions.

11. The inspection apparatus of claim 1, wherein the computer unit is arranged to correlate the 3D model of the machine component with the design model of the machine component.

12. The inspection apparatus of claim 1, wherein some or all inspection sensors of the plurality of inspection sensors are non-contact type and/or contact type.

13. The inspection apparatus of claim 1, wherein the plurality of inspection sensors comprises:
at least one inspection sensor for inspecting a surface geometry of the machine component, and
at least one inspection sensor configured to inspect a surface layer or a sub-surface layer or a core of the machine component.

14. The inspection apparatus of claim 1, further comprising:
a support element configured to support the machine component to be inspected, and
at least one industrial robot with an articulated arm, preferably a five-axis or six-axis articulated arm,
wherein the support element is preferably rotatable and/or tiltable;
wherein the articulated arm is configured to carry inspection sensors;
wherein the computer unit is arranged to control the support element and/or the articulated arm.

15. The inspection apparatus of claim 1, further comprising:
at least one industrial robot with an articulated arm, preferably a five-axis or six-axis articulated arm, configured to grasp,
move and/or manipulate the machine component to be inspected; wherein the computer unit is arranged to control the articulated arm;
wherein some or all inspection sensors of the plurality of inspection sensors are fixedly mounted to a frame or structure of the inspection apparatus at different positions.

16. The inspection apparatus of claim 1, further comprising:
a container;
wherein the container houses at least the computer unit, the scanner, the plurality of inspection sensors, and preferably at least one industrial robot with an articulated arm;
wherein the container has an opening through which the machine component to be inspected is introduced into an inspection room;
wherein the container is preferably configured to be transportable.

17. A method for automatically inspecting a machine component after a period of machine operation through an inspection apparatus comprising a computer unit, a computer unit including inspection criteria, the method comprising an initial phase, afterwards one or more different inspection phases, and afterwards a final phase;
wherein the initial phase comprises the steps of:
A) scanning the machine component dismounted from the machine,
B) creating a 3D model of the machine component based on the scanning of the machine component,
D) receiving and/or retrieving a design model of the machine component;
wherein an inspection phase comprises the steps of:
E) inspecting the machine component through at least one inspection sensor,
F) generating inspection information based on the at least one inspecting step,
G) associating the inspection information to the 3D model of the machine component so to create an annotated 3D model of the machine component; wherein the final phase comprises the steps of:
I) performing a simulation on the machine component so to determine a status of one or more regions of the machine component, taking into account the created 3D model of the machine component, inspection data generated from at least one inspecting step, and the received and/or retrieved design model of the machine component;
H) applying one or more inspection criteria to results of the simulation performed so to determine whether the machine component is serviceable.

18. The method of claim 17,
wherein the final phase further comprises the step of:
L) applying one or more inspection criteria to results of the simulation performed so to determine whether the machine component is repairable.

19. The method of claim 17,
wherein at step I the simulation performed is a mechanical or thermal or chemical simulation on the machine component and is aimed at determining a mechanical or thermal or chemical status of one or more regions of the machine component, or
wherein at step I the simulation performed is performed under machine operation conditions.

20. The method of claim 17,
wherein at least one of the criteria is based on a duration and/or a condition of the period of machine operation, or
wherein at least one of the criteria is a multiple criterion, wherein a multiple criterion is based on at least two inspection steps.
